(19) United States
(12) Patent Application Publication
(10) Pub. No.: US 2015/0171270 A1
(43) Pub. Date: Jun. 18, 2015

(54) LED For Plant Illumination

(71) Applicant: Xiamen Sanan Optoelectronics Technology Co., Ltd., Xiamen, FJ (CN)

(72) Inventors: Hongliang Lin, Xiamen (CN); Chaoyu Wu, Xiamen (CN); Yi-Jui Huang, Xiamen (CN); Chun-I Wu, Xiamen (CN); Ching-Shan Tao, Xiamen (CN)

(21) Appl. No.: 14/415,037

(22) PCT Filed: May 16, 2013
(86) PCT No.: PCT/CN2013/075684

§ 371 Date: Jan. 15, 2015

(30) Foreign Application Priority Data
Mar. 7, 2013 (CN) 201310072627.3

(51) Int. Cl. H01L 33/12; H01L 33/30; A01G 7/04; H01L 33/00

(52) U.S. Cl. CPC H01L 33/12; H01L 33/0025; H01L 33/30; A01G 7/045

(57) ABSTRACT

An LED used for plant illumination, comprising a substrate (11), a PN-junction light-emitting part arranged on the substrate (11). The light-emitting part has a strained light-emitting layer with component formula of GaXIn(1−X)AsYP(1−Y) (0<X<1 and 0<Y<1). The light-emitting part has a barrier layer, forming a 2˜40-pair alternating-layer structure with the strained light-emitting layer. The structure adopts a new light-emitting material GaXIn(1−X)AsYP(1−Y), which can significantly improve the light-emitting efficiency by 50%-100%.

This application claims priority to Chinese Patent Application No. 201310072627.3 titled “Light-emitting diode used for plant illumination”, and filed on Mar. 7, 2013, which is hereby incorporated by reference in its entirety.

### TECHNICAL FIELD

The present disclosure relates to an LED, and more particularly, to an LED used for plant illumination.

### BACKGROUND

In recent years, many studies have been made on plant cultivation via artificial light source. In particular, the plant cultivation by the light-emitting diode (LED) attracts much attention due to excellent monochromaticity, energy saving, long service life and small size.

Plant illumination mainly includes the plant growth light and aquarium light. The plant growth light supplements the light source when the natural light is insufficient, which complements the sunlight and adjusts the agricultural product growth. The aquarium light not only improves the growth of aquatic plants, but also has the lighting effect for sightseeing.

Compared with traditional plant illumination, the LED plant illumination is advantageous in the following aspects: i) energy saving. The LED plant illumination may directly generate the light for plant with same-lumen photon, which consumes little power; ii) high efficiency. As monochromatic light, the LED can generate light waves matching the plant requirement, which cannot be achieved by traditional plant light; iii) the LED plant illumination has rich wavelength types capable of controlling the plant flowering, fruiting, plant height and nutrient contents. With the further improvement of LED plant illumination technology, it will be used for multi-layer 3D combined cultivation systems with less system heat, small space and low thermal load.

### SUMMARY

The present invention discloses an LED for plant illumination, the new light-emitting material GaXIn(1−X)AsYP(1−Y) of which can significantly improve the light-emitting efficiency by 50%-100%.

An LED for plant illumination, comprising a substrate arranged at the PN junction light-emitting part of the substrate. The light-emitting part has a strained light-emitting layer with component formula of GaXIn(1−X)AsYP(1−Y) (0<X<1 and 0<Y<1).

In some embodiments, the light-emitting part has a strained light-emitting layer with component formula of GaXIn(1−X)AsYP(1−Y) (0<X<1 and 0<Y<0.2).

Further, the light-emitting part has a strained light-emitting layer with component formula of GaXIn(1−X)AsYP(1−Y) (0<X<1 and 0<Y<0.1).

Further, the light-emitting part has a strained light-emitting layer with component formula of GaXIn(1−X)AsYP(1−Y) (0<X<1 and 0<Y<0.05).

Further, the light-emitting part has a barrier layer, forming a 2˜40-pair alternating-layer structure with the strained light-emitting layer.

Further, each alternating-layer structure is 5-100 nm thick.

Further, the barrier layer has a component formula of (AlXGa1−X)YIn(1−Y)P (0.3≦X≦1 and 0<Y<1).

Further, the substrate material may be GaAs, GaP or any one of their combinations.

Further, the invention also comprises a buffer layer between the substrate and the light-emitting part.

Further, the invention also comprises a window layer arranged on the light-emitting part.

Further, the window layer material is GaP.

Further, the window layer is 0.5-15 μm thick.

Further, in the LED for improving photosynthesis during plant cultivation, the peak light-emitting wavelength of the strained light-emitting layer is 650-750 nm.

Further, in the LED for improving photosynthesis during plant cultivation, the peak light-emitting wavelength of the strained light-emitting layer is 700-750 nm.

An LED for plant illumination, comprising a light-emitting part of strained light-emitting layer on the substrate with component formula of GaXIn(1−X)AsYP(1−Y) (0<X<1 and 0<Y<1). The strained light-emitting layer material is GaInAsP, which can improve the light-emitting efficiency of the strained light-emitting layer. Besides, the material is helpful for improving life stability due to the lack of Al component.

In addition, by adjusting the composition and thickness of the strained light-emitting layer, the light-emitting wavelength from the strained light-emitting layer is in a range of 650-750 nm. Further, a window layer is provided at the light-emitting part of the LED for plant illumination, which is transparent to the light-emitting wavelength, and therefore will not absorb the light from the light-emitting part. Besides, it has the current spreading function.

Hence, according to this disclosure, a high output power and/or highly efficient LED capable of generating a large quantity of light-emitting wavelength of 650-750 nm is provided.

Other features and advantages of the present disclosure will be described in detail in the following specification, and moreover, will become obvious partially through the Specification or understood through implementation of this invention.

### BRIEF DESCRIPTION OF THE DRAWINGS

The accompanying drawings are included to provide a further understanding of the invention and constitute a part of this specification. Together with the embodiments, they are illustrative and not restrictive. In addition, the drawings are merely illustrative, which are not drawn to scale.

FIG. 1 is a sectional structure diagram of LED for plant illumination according to this disclosure.

### EMBODIMENTS

Based on study results so far, the light-emitting wavelength of light sources suitable for plant growth is near 450 nm (blue light) and 600-750 nm (red light).

The traditional light-emitting layer for plant illumination is AlGaAsP or AlGaAs. However, the LED with light-emitting layer made of AlGaAsP or AlGaAs has low light-emitting output power. To promote feasible light source of LED for plant cultivation, it is necessary to develop LED with high output power and/or high efficiency in consideration of energy and cost saving.

The following embodiments provide a LED with 650-750 nm wavelength suitable for plant illumination, featured by high output power and stable service life.

The GaInP light-emitting wavelength is near 640 nm and the GaAs light-emitting wavelength is near 850 nm. In the following embodiments, the light-emitting layer GaInP material is doped with As and the thickness and strain capacity of the strained light-emitting layer are adjusted; therefore, an LED composed of new epitaxial structure for plant illumination is developed that is suitable for wavelength of 650-750 nm.

Detailed descriptions will be given below about this disclosure with reference to accompanying drawings and embodiments.

### Embodiment 1

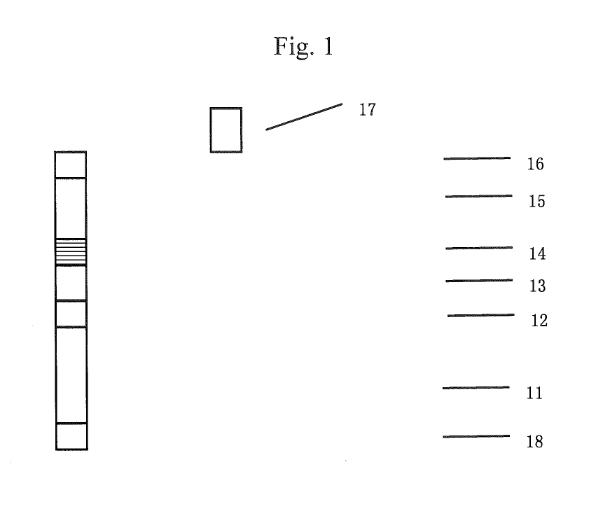

As shown in FIG. 1, an LED comprises: a substrate 11, divided into a first surface and a second surface; a light-emitting part, which consists of a stack of semiconductor material layers, including a buffer layer 12, a first restriction layer 13, a light-emitting layer 14 and a second restriction layer 15, sequentially from down up and formed on the first surface of the substrate 11; a window layer 16 formed on a partial region of the second restriction layer 15 of the light-emitting part; a second electrode 17, formed on the window layer 16; and a second electrode 18, formed on the second surface of the substrate 11.

In the element, the substrate 11 material may be GaAs, GaP or any one of their combinations.

The buffer layer 12 can mitigate lattice imperfection of the epitaxially growing substrate but is not a necessary film for the element.

The light-emitting part consists of an alternating layer (of strained light-emitting layer and barrier layer) structure, including at least two 2 pairs (preferably 2-40 pairs). The structure of each pair of alternating-layers is, without limitation to, 5-100 nm thick. A structure of a plurality of alternating layers can effectively improve the saturation current of the element. In this embodiment, the pair number of the alternating layer structure of alternating strained light-emitting layer and barrier layer is 6. The structure of each pair is 40 nm thick and the total thickness is 240 nm.

The strained light-emitting layer material is Al-free GaInAsP with component formula of GaXIn(1−X)AsYP(1−Y) (0<X<1 and 0<Y<1). Further, to better control the peak wave of the light-emitting layer within 650 nm-750 nm, the Y value is preferably 0<Y<0.2. In this embodiment, X=0.5 and Y=0.01.

The barrier layer material is AlGaInP with component formula of (AlXGa1−X)YIn(1−Y)P (0.3≦X≦1 and 0<Y<1). In this embodiment, X=0.5 and Y=0.5.

The window layer is GaP (thickness: 0.5 μm-15 μm) and is capable of current expansion. The window layer is not a necessary film for the element, which can be chosen based on the process parameters.

Refer to Table 1 for the optical-electrical characteristics of the 42×42 mil large-power quaternary LED element structure. As shown in Table 1, based on the flowing current results of the first electrode and second electrode after being powered on, the element emits red light with an average peak wavelength of 685.6 nm. When the 350 mA current flows through in forward direction, the average forward voltage value is 2.25 V and the output power is 250.3 mW.

TABLE 1

| | VF/V | Po/mW | WLD/nm | WLP/nm |
|---|---|---|---|---|
| No. 1 | 2.26 | 248.5 | 656.2 | 686.0 |
| No. 2 | 2.23 | 252.1 | 656.2 | 685.1 |
| Average | 2.25 | 250.3 | 656.2 | 685.6 |

### Embodiment 2

In comparison with Embodiment 1, t the following is the same: in the 42×42 mil quaternary LED element structure of this embodiment, the pair number of the alternating-layer (of strained light-emitting layer and barrier layer) structure is 6. The structure of each pair is 60 nm thick and the total thickness is 360 nm. The difference is that: the strained light-emitting layer is GaXIn(1−X)AsYP(1−Y) (X=0.5 and Y=0.025). Based on the flowing current results of the first electrode and second electrode after being powered on, the element emits red light with average main wavelength of 680.2 nm and average peak wavelength of 714.9 nm. When the 350 mA current flows through in forward direction, the average forward voltage value is 2.22 V and the output power is 232.7 mW.

### Embodiment 3

In comparison with Embodiment 1, the difference is that: the strained light-emitting layer of the 42×42 mil quaternary LED element structure of this embodiment is GaXIn(1−X)AsYP(1−Y) (X=0.5 and Y=0.04).

Refer to Table 2 for the optical-electrical characteristics of the 42×42 mil quaternary LED element structure. As shown in Table 2, based on the flowing current results of the first electrode and second electrode after being powered on, the element emits red light with average peak wavelength of 722.0 nm. When the 350 mA current flows through in forward direction, the average forward voltage value is 2.18 V and the output power is 216.5 mW.

TABLE 2

| | VF/V | Po/mW | WLD/nm | WLP/nm |
|---|---|---|---|---|
| No. 1 | 2.19 | 215.7 | 693.7 | 721.7 |
| No. 2 | 2.20 | 222.7 | 697.4 | 723.5 |
| No. 3 | 2.16 | 220.1 | 701.7 | 723.5 |
| No. 4 | 2.19 | 207.6 | 691.5 | 719.3 |
| Average | 2.19 | 216.5 | 696.1 | 722.0 |

### Embodiment 4

In comparison with Embodiment 3, the difference is that: the strained light-emitting layer of the 42×42 mil quaternary LED element structure of this embodiment is GaXIn(1−X)AsYP(1−Y) (X=0.5 and Y=0.05). Based on the flowing current results of the first electrode and second electrode after powering on, the element emits red light with average main wavelength of 712.3 nm and average peak wavelength of 739.5 nm. When the 350 mA current flows through in forward direction, the average forward voltage value is 2.21 V and the output power is 202.2 mW.

### Embodiment 5

In comparison with Embodiment 3, the difference is that: in the 42×42 mil quaternary LED element structure of this embodiment, the pair number of alternating-layer (of strained light-emitting layer and barrier layer) structure is 9. The structure of each pair is 50 nm thick and the total thickness is 450 nm. Based on the flowing current results of the first electrode and second electrode after powering on, the element emits red light with average main wavelength of 701.5 nm and average peak wavelength of 733.5 nm. The saturation current is above 2,000 mA. When the 350 mA current flows through in forward direction, the average forward voltage value is 2.24 V and the output power is 223.9 mW.

To sum up, in the LED element structure for improving photosynthesis during plant cultivation, the peak light-emitting wavelength can be controlled within 650-750 nm by adjusting the composition of strained light-emitting layer, component value range and the pair number and thickness range of the alternating-layer (of strained light-emitting layer and barrier layer) structure, thereby achieving high output power. Besides, the material is helpful for improving life stability due to the lack of Al component.

1. An LED used for plant illumination, comprising:
a substrate;
a PN junction light-emitting part is arranged on said substrate;
the light-emitting part has a strained light-emitting layer with component formula of GaXIn(1−X)AsYP(1−Y), 0<X<1 and 0<Y<1.

2. An LED used for plant illumination according to claim 1, wherein 0<Y<0.2.

3. An LED used for plant illumination according to claim 1, wherein 0<Y<0.1.

4. An LED used for plant illumination according to claim 1, wherein 0<Y<0.05.

5. An LED used for plant illumination according to claim 1, wherein the light-emitting part has a barrier layer, forming a 2˜40-pair alternating-layer structure with the strained light-emitting layer.

6. An LED used for plant illumination according to claim 5, wherein each alternating-layer structure is 5-100 nm thick.

7. An LED used for plant illumination according to claim 1, wherein the barrier layer has a component formula of (AlXGa1−X)YIn(1−Y)P (0.3≦X≦1 and 0<Y<1).

8. An LED used for plant illumination according to claim 1, wherein the LED also comprises a GaP window layer on the light-emitting part.

9. An LED used for plant illumination according to claim 1, wherein the peak light-emitting wavelength of the strained light-emitting layer is 650-750 nm.

10. An LED used for plant illumination according to claim 1, wherein the peak light-emitting wavelength of the strained light-emitting layer is 700-750 nm.
